(19) United States
(12) Patent Application Publication
(10) Pub. No.: US 2005/0050724 A1
(43) Pub. Date: Mar. 10, 2005

(54) Method for fabricating high density of multi-polyimide-layer DPC lines on a ceramic board

(76) Inventor: Shao-Pin Ru, Taipei (TW)

Correspondence Address: DELLETT AND WALTERS, P. O. BOX 2786, PORTLAND, OR, 97208-2786, US

(21) Appl. No.: 10/659,883

(22) Filed: Sep. 10, 2003

(51) Int. Cl. H05K 1/00; H05K 3/10

(52) U.S. Cl. 29/852; 174/250; 29/846

(57) ABSTRACT

A method for fabricating high integration multi-layer DPC lines on a ceramic board is to make the high density of multi-layer metal lines with insulating layer and the fine through holes. The metal lines are able to form in the different insulating layers, so as to the density of the metal lines is high. Besides the through holes defined in the ceramic board are fine, so that the space where the metal lines formed on is larger than the normal. Thus the fine through holes are stuffed with the conductive material, so that the quantity of the inductor of the metal lines is as possible as decreasing.

### BACKGROUND OF THE INVENTION

1. Field of the Invention

The present invention relates to a method for fabricating high density of multi-polyimide-layer directly plated copper (DPC) lines on a ceramic board and more particularly to the method providing high density of the lines on the ceramic board.

2. Description of Related Art

Surface Mounted Technology (SMT) has resulted in advances in miniaturization of electronics and this is a key to make the electronic products to become increasingly smaller than normal. However, while designing the electronic elements to be miniaturized, some problems have occurred in this miniaturization technology, such as how to design a high density of an integrated circuit in a limited area of a chip and how to dissipate heat from an operating chip. Of particular concern is the quantity of inductors included in a line of the integrated circuit when that circuit is adapted to the Radio Frequency (RF) circuit. Because the quantity of inductors of each line is increased as the RF circuit applies a higher frequency, and the quantity of the inductors causes the RF circuit to have abnormal functions during operating.

In a DPC process for fabricating a ceramic chip, the conductive through holes define in the ceramic board to electronically interconnect the circuits formed on the upper and bottom face of the ceramic board. The conductive through holes in a ceramic board by using a drilling machine and then the inner surface of the through holes are plated with copper, that is each of through holes is not stuffed all the conductive copper. Because the drilling machine is not able to cut very fine holes required in miniaturization, the total area of the through holes takes up considerable space of the ceramic board. On the other hand, the density of the integrated circuit on the board does not increase.

To overcome those shortcomings, the present invention provides simple and easy steps and good production ability to mitigate and obviate the aforementioned problems.

### SUMMARY OF THE INVENTION

The main objective of the present invention is to provide an effective method for increasing the density of the integration of the metal lines on a limited space of a ceramic board. Besides, controlling the low quantity of the inductor of a metal line ensures the RF circuit in a normal function state. The method for fabricating the DPC lines comprises the following steps:
defining fine through holes in the ceramic board by using laser beams or a photolithography technology;
forming first conductive pillars in the fine through holes;
forming first metal lines on an upper surface and a bottom surface of the ceramic board, wherein the conductive pillars connect with the first metal lines in the upper surface and a bottom surface;
applying insulating layers on the two surfaces of the ceramic board, the insulating layer covers the bottom surface and the first metal lines, and then columns corresponded to the first metal lines define in a portion of the insulating layer; and
forming second metal lines in the insulating layer, the columns connect the second metal line with the first metal lines.

Therefore, fabricating the high density of metal lines on the ceramic board is easy by the fine through holes and the insulating layers. Besides the conductive pillars are stuffed in the fine through holes, the quantity of inductors effectively decreases. That is, the power loss of the metal lines is low.

The other objective of the present invention is to provide an effective method for dissipating heat from an operating metal lines by using the ceramic board and the polyimide insulating layers.

Other objects, advantages, and novel features of the invention will become more apparent from the following detailed description when taken in conjunction with the accompanying drawings.

### BRIEF DESCRIPTION OF THE DRAWINGS

FIG. 1 is a flow of a method in accordance with the present invention explaining the steps of the method;

FIGS. 2A and 2B are cross sectional views of making a conductive pillar on a ceramic board step of the method in accordance with the present invention;

FIG. 2C is cross sectional view of forming first metal lines on an upper and bottom surfaces of the ceramic board step of the method in accordance with the present invention;

FIG. 2D is cross sectional view of forming an insulating layer on the upper and bottom surfaces of the ceramic board step of the method in accordance with the present invention; and

FIG. 2E is cross sectional view of forming second metal lines on the insulating layer step of the method in accordance with the present invention.

### DETAILED DESCRIPTION OF THE PREFERRED EMBODIMENT

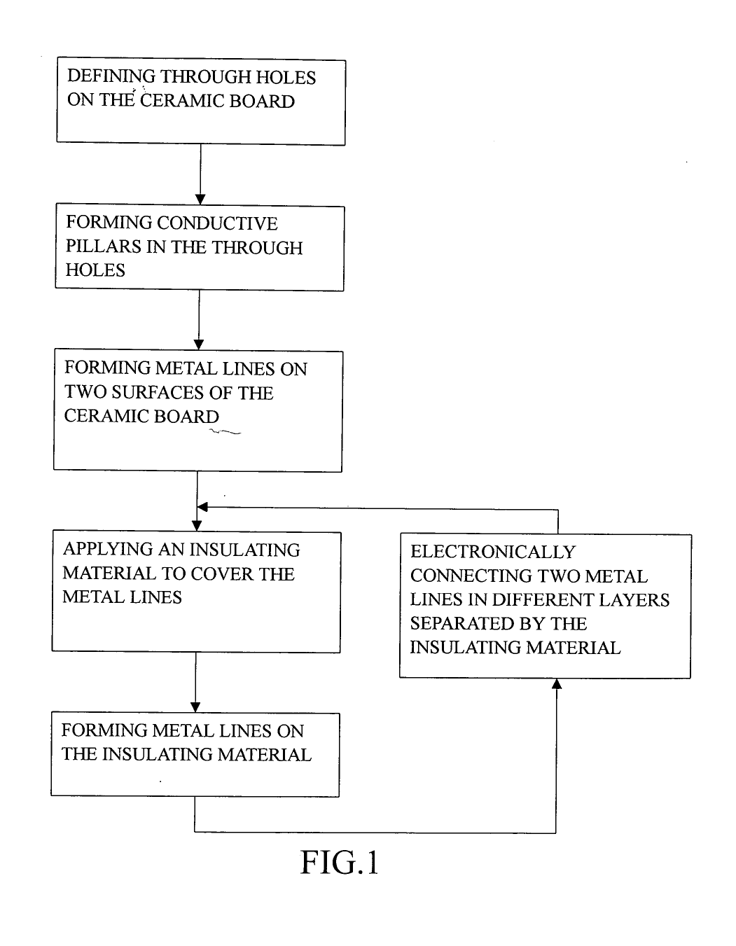

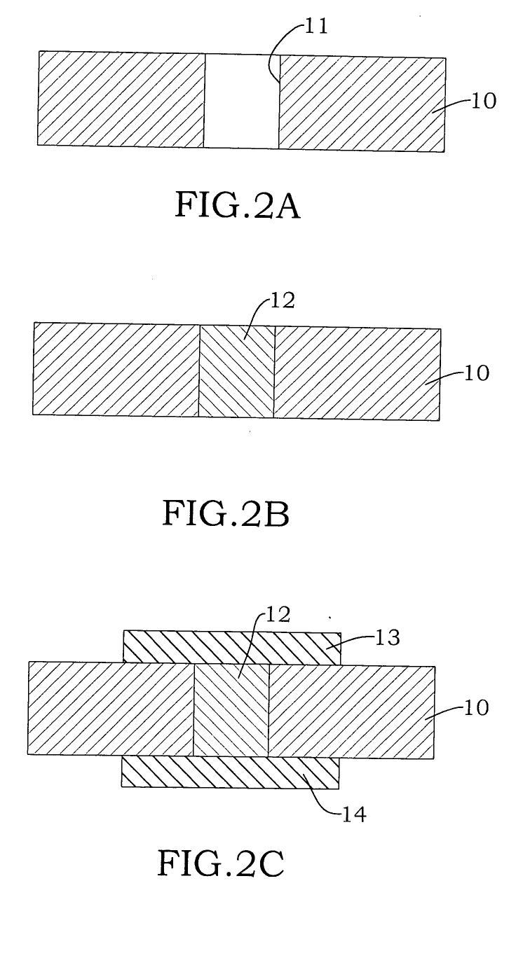

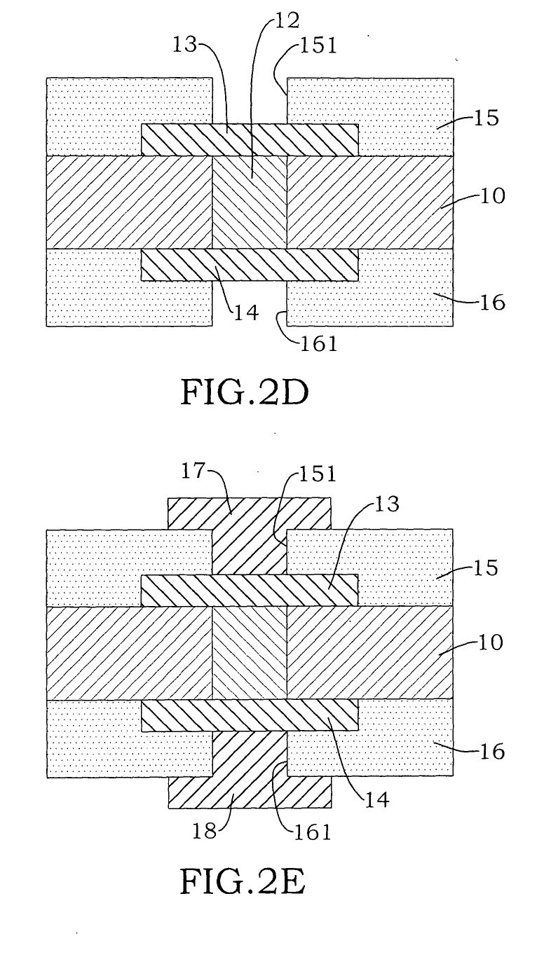

With reference to FIGS. 1 and 2A to 2E, the method for fabricating a high density of multi-layer DPC lines on a ceramic board comprises the following steps:
defining through holes (11) in a portion of the ceramic board (10) by a photolithography technology or laser beams as shown in FIG. 2A;
forming a conductive pillar (12) in each of the through holes (11), that is, a conductive material is put in the through hole to (11) become the first conductive pillar (12), as shown in FIG. 2A;
forming first metal lines (13)(14) on an upper surface and a bottom surface of the ceramic board (10), wherein the conductive pillar (12) connects with the first metal lines (13)(14) formed on the upper surface and bottom surface of the ceramic board (10);
applying an insulating layer (15) (16) on the upper surface and the bottom surface of the ceramic board (10) to cover the upper surface and the bottom surface of the ceramic board (10) and the first metal lines (13)(14), and then columns (151) (161) corresponded to the first metal lines (13)(14) respectively define on the insulating layer (15)(16), wherein the material of the insulating layer (15)(16) is a polyimide, as shown in FIG. 2D; and
forming second metal lines (17)(18) in the insulating layer (15)(16), wherein when using the conductive material, such as titanium or copper, to form the second metal lines, and the columns (151)(161) for electronically connecting the second metal lines (17)(18) with the first metal lines (13)(14), as shown in FIG. 2E.

The invention provides a multi-polyimide layer on the ceramic board by insulating layers, that is more metal lines form on each of the polyimide layer. To fabricate the ceramic board with the multi-polyimide layer is easy that the previous two steps, ie, forming the insulating layer step and forming the second metal lines step. Meanwhile, an electronically connecting step is performed after the each applying insulating layer step to connect the two metal lines in different insulating layers. For example the column (151) is defined on the insulating layer (15) to connect with the first metal lines and the second metal lines (17) separated by the insulating layer (15).

Because the ceramic board has special characteristics, such as a low power loss and great effective dispersing heat performance, and the fine through holes are defined by the photolithography technology or the laser beams. Therefore, the total size of the through holes does not occupy considerable space of the ceramic board, and thus the density of the integration of the metal lines is accordingly large. Besides, using the insulating layers on the surfaces of the ceramic board is able to increase the space where metal lines formed, so that the density of the integration of the metal lines is increased.

According to the above description about the invention, the method provides a high integration of lines on the ceramic board via the fine through holes and the insulating material, especially the ceramic board with high integration of the integrated circuit adapted to apply on the RF circuit. Meanwhile the conductive pillars and conductive columns fill in the fine through holes, so that the quantity of the inductors of the conductive pillars and conductive columns are fewer than the inductors of the conventional conductive holes made by the drilling machine and the electroplate technology.

Although the present invention has been explained in relation to its preferred embodiment, it is to be understood that many other possible modifications and variations can be made without departing from the spirit and scope of the invention as hereinafter claimed.

1. A method for fabricating a ceramic board with high integration of multi-polyimide-layer DPC lines, comprising the following steps:
defining fine through holes on a portion of a ceramic board;
forming conductive pillars in the fine through holes by a conductive material;
forming first metal lines on an upper surface and a bottom surface of the ceramic board, wherein the conductive pillars connect with the first metal lines respectively formed on the upper surface and the bottom surface of the ceramic board;
applying an insulating layer on the upper surface and the bottom surface of the ceramic board to cover the upper surface and the bottom surface of the ceramic board and the first metal lines; and
forming second metal lines in the insulating layer, wherein when using conductive material to form the second metal lines.

2. The method as claimed in claim 1, wherein the method further comprises an electronically connecting step after the applying insulating layer step, wherein the electronically connecting step is forming columns in the insulating layer for electronically connecting the first metal lines with the second metal lines.

3. The method as claimed in claim 1, wherein the fine through holes defined in the ceramic board are cut by using laser beams.

4. The method as claimed in claim 1, wherein the fine through holes defined in the ceramic board are cut by using a photolithography technology.

5. The method as claimed in claim 1, wherein the conductive material of the conductive pillars is copper or silver material.

6. The method as claimed in claim 1, wherein the conductive material of the conductive pillars is silver material.

7. The method as claimed in claim 1, wherein the conductive material of the first and second metal lines is titanium.

8. The method as claimed in claim 1, wherein the conductive material of the first and second metal lines is copper material.
